(19) United States
(12) Patent Application Publication
(10) Pub. No.: US 2025/0301762 A1
(43) Pub. Date: Sep. 25, 2025

(54) ADJACENT LOGIC CELLS HAVING BACK-TO-BACK VIAS

(71) Applicant: QUALCOMM Incorporated, San Diego, CA (US)

(72) Inventors: Shreesh NARASIMHA, Charlotte, NC (US); Yan SUN, San Diego, CA (US)

(21) Appl. No.: 18/610,898

(22) Filed: Mar. 20, 2024

(51) Int. Cl. H01L 21/8238; H01L 21/8234; H01L 27/02; H01L 27/088

(52) U.S. Cl. CPC H10D 84/038; H10D 84/0147; H10D 84/0186; H10D 84/83; H10D 89/10

(57) ABSTRACT

An electronic device having at least two adjacent logic cells is disclosed. The electronic device includes at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and a spacer disposed between and separating the first via and the second via.

### FIELD OF DISCLOSURE

The present disclosure generally relates to logic cells, and more particularly, to adjacent logic cells having back-to-back vias, and methods of making the back-to-back vias.

### BACKGROUND

Integrated circuit (IC) technology has achieved great strides in advancing computing power through miniaturization of electrical components. An IC may be implemented in the form of an IC chip that has a set of circuits integrated thereon. In some implementations, one or more IC chips can be physically carried and protected by an IC package, where various power and signal nodes of the one or more IC chips can be electrically coupled to respective conductive terminals of the IC package via electrical paths formed in a package substrate of the IC package. Various packaging technologies can be found in many electronic devices, including processors, servers, radio frequency (RF) integrated circuits, etc. Advanced packaging and processing techniques can be used to implement complex devices, such as multi-electronic component devices and system on a chip (SOC) devices, which may include multiple function blocks, with each function block designed to perform a specific function, such as, for example, a microprocessor function, a graphics processing unit (GPU) function, a communications function (e.g., WiFi, Bluetooth, and other communications), and the like.

The semiconductor industry has pursued the path of miniaturization, seeking to pack more functionality into smaller areas of silicon. One aspect of this trend is the design and fabrication of logic cells, the basic units of digital circuits, characterized by their configuration of transistors and interconnects. Traditionally, a common form of logic cell design has been the 6-track (6T) cell, which has served as a standard for semiconductor manufacturing. However, as the industry pushes for greater density and performance, there is a shift toward reducing the track size, moving from 6T to 5T, and fewer tracks (e.g., 4T), which introduces manufacturing challenges.

### SUMMARY

The following presents a simplified summary relating to one or more aspects disclosed herein. Thus, the following summary should not be considered an extensive overview relating to all contemplated aspects, nor should the following summary be considered to identify key or critical elements relating to all contemplated aspects or to delineate the scope associated with any particular aspect. Accordingly, the following summary has the sole purpose to present certain concepts relating to one or more aspects relating to the mechanisms disclosed herein in a simplified form to precede the detailed description presented below.

In an aspect, an electronic device having at least two adjacent logic cells includes at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and a spacer disposed between and separating the first via and the second via.

In an aspect, a semiconductor logic device having at least two adjacent logic cells includes at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and a spacer disposed between and separating the first via and the second via.

In an aspect, a method of forming a semiconductor logic device includes forming at least two adjacent logic rows; forming a spacer about a peripheral edge of a first logic row of the at least two adjacent logic rows; and forming at least one pair of back-to-back vias in adjacent logic cells of the at least two adjacent logic rows, wherein the at least one pair of back-to-back vias includes a first via and a second via that are separated by the spacer. Other objects and advantages associated with the aspects disclosed herein will be apparent to those skilled in the art based on the accompanying drawings and detailed description.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings, which are presented solely for illustration and not limitation of the disclosure.

FIG. 1 illustrates a logic cell having a five-track (5T) height layout, according to aspects of the disclosure.

FIG. 2 shows a mirrored arrangement of logic cells, according to aspects of the disclosure.

FIG. 3 illustrates a logic cell having a four-track (4T) height layout, according to aspects of the disclosure.

FIG. 4 shows a mirrored arrangement of logic cells, according to aspects of the disclosure.

FIG. 5 is a top plan view showing an example of an intermediate structure during the formation of a mirrored arrangement of 4T logic cells and, according to aspects of the disclosure.

FIG. 6 shows a cross-sectional view of the intermediate structure taken along line VI-VI of FIG. 5, according to aspects of the disclosure.

FIG. 7A through FIG. 7H show exemplary processing operations that may be used to form back-to-back vias in adjacent logic cells, according to aspects of the disclosure.

FIG. 8 is a plan view of an example arrangement of logic rows 800, according to aspects of the disclosure.

FIG. 9 is a flowchart showing an example method for fabricating a semiconductor logic device, according to aspects of the disclosure.

FIG. 10 illustrates a profile view of a package that includes a surface mount substrate, an integrated device, and an integrated passive device, according to aspects of the disclosure.

FIG. 11 illustrates an example method for providing or fabricating a package that includes an integrated device comprising adjacent logic cells having back-to-back vias, according to aspects of the disclosure.

FIG. 12 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (POP), System in Package (SiP), or System on Chip (SoC).

In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Aspects of the present disclosure are illustrated in the following description and related drawings directed to specific embodiments. Alternate aspects or embodiments may be devised without departing from the scope of the teachings herein. Additionally, well-known elements of the illustrative embodiments herein may not be described in detail or may be omitted so as not to obscure the relevant details of the teachings in the present disclosure.

In certain described example implementations, instances are identified where various component structures and portions of operations can be taken from known, conventional techniques and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. It will also be understood that when a layer is described as “over,” “overlying,” “under,” “underlying,” another layer does not necessarily preclude the use of intermediate layers and/or materials that may otherwise be used to ensure adhesion between the layers. Still further, it will be understood that when a layer is described as “over,” “overlying,” “under,” “underlying,” another layer that such terms are used with reference to the orientations of such layers as depicted in the reference frame shown in the corresponding figures.

In an aspect, the present disclosure is directed to logic cells having reduced track sizes and fabrication techniques for making such logic cells. Logic cells constitute efficient configurations of semiconductor devices (e.g., transistors) that form the fundamental building blocks of complex digital circuits used in electronic devices. Multiple logic cells having the same fundamental structure may be interconnected with one another in a manner that performs a desired digital operation. To this end, certain logic cells may be positioned adjacent to one another in a mirrored arrangement.

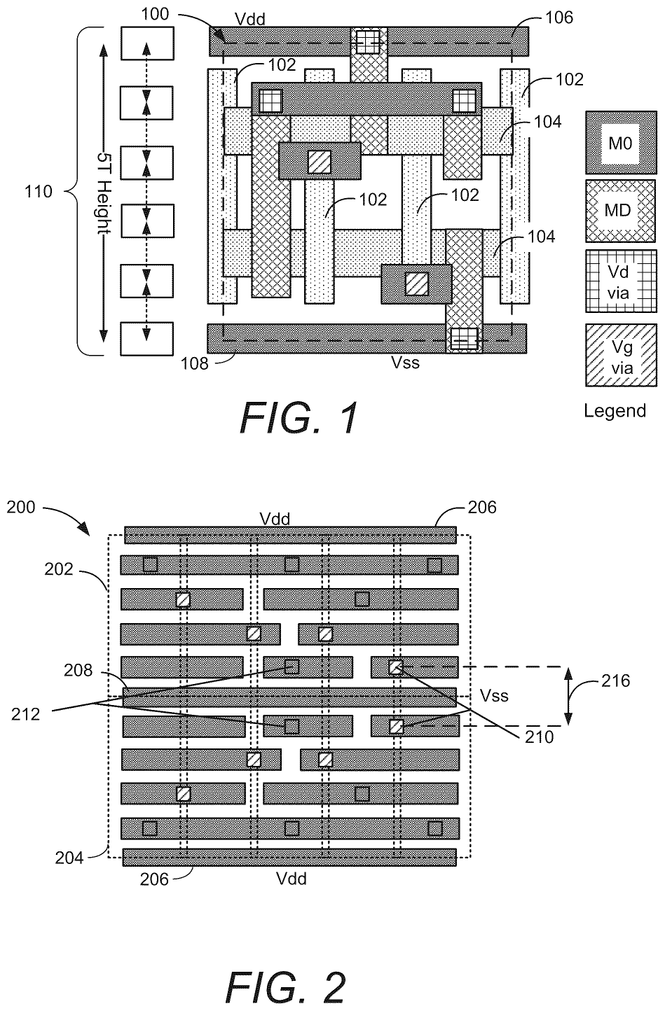

FIG. 1 illustrates a logic cell 100 having a five-track (5T) height layout, according to aspects of the disclosure. In this example, the logic cell 100 is configured as a NAND2 cell. Here, the logic cell 100 includes a plurality of gate structures 102 and a plurality of doped regions 104 (e.g., forming the source/drain regions). A first power bus 106 is disposed at a top portion of the logic cell 100 and may be used to carry the supply voltage Vdd. A second power bus 108 is disposed at a lower portion of the logic cell 100 and may be used as the ground reference Vss with respect to supply voltage Vdd.

The logic cell 100 further includes a plurality of metallization layers. In this example, two metallization layers are shown (although there may be many more depending on the configuration of the logic cell 100), including metallization layer M0 and metallization layer MD (see Legend of FIG. 1). In an aspect, the metallization layer M0 is the first or the lowest metallization layer that is directly above the active components of the semiconductor device (e.g., the Metal-Oxide-Semiconductor Field-Effect Transistors (MOSFETs) within the logic cell 100). The metallization layer M0 is often the metallization layer that is closest to the silicon substrate where the active devices are formed. In an aspect, the metallization layer MD (e.g., Metal Drain metallization layer) forms the drain contacts of the MOSFETs of the logic cell, where the drain is one of the three primary components of a MOSFET structure, the other two being the gate and the source. In an aspect, the drain is where current flows out of the MOSFET (when the MOSFET is on), and the metallization layer MD provides a low-resistance conductive path for this current. The metallization layer MD layer may be directly connected to the drain region of the MOSFET, ensuring efficient electron or hole flow depending on the MOSFET type (N-type or P-type).

The logic cell 100 further includes a plurality of vias that interconnect the metallization layers of the logic cell 100. In the example shown in FIG. 1, two via types are shown. Here, the illustrated vias include Vd vias and Vg vias (see Legend in FIG. 1). In an aspect, the Vd vias are responsible for connecting the drain region of the MOSFETs to the appropriate metallization layer that carries the drain voltage (e.g., metallization layer MD) or connects to other circuitry. In an aspect, the Vg vias connect the gate regions of the MOSFETs to the metallization layer that either carries the gate voltage or forms part of the gate structure itself, depending on the MOSFET's design.

In accordance with certain aspects of the disclosure, logic cells (e.g., logic cell 100) may be stacked in a mirrored arrangement to construct more complex digital circuits that use the logic cells as their functional building blocks. A mirrored arrangement of multiple logic cells offers several advantages. In an aspect, by aligning the logic cells mirrored, the design minimizes unused silicon areas, effectively increasing the number of logic cells that can be integrated per unit area of a semiconductor substrate. In certain scenarios, this arrangement shortens the total length of interconnects required between the logic cells, thereby reducing signal propagation delays, minimizing power loss, and enhancing the overall speed of electronic data transfer within the device. Further, in certain scenarios, the mirrored configuration aids in heat distribution, as it allows for more uniform heat dissipation pathways, preventing hotspots and promoting a more stable operating environment for the components of the logic cells.

FIG. 2 shows a mirrored arrangement of logic cells 200, according to aspects of the disclosure. In this example, the mirrored arrangement of logic cells 200 includes a first logic cell 202 that is mirrored with a second logic cell 204. In this example, the first and second logic cells 202 and 204 may have the same layout as logic cell 100 shown in FIG. 1. Here, the first and second logic cells 202 and 204 are mirrored so that the power buses 206 providing the supply voltage Vdd are disposed at opposite sides of the mirrored arrangement of logic cells 200 while the power bus 208 providing the ground voltage Vss is shared by the first and second logic cells 202 and 204. In an aspect, the power buses 206 and 208 may be formed as part of the metallization layer M0.

The first and second logic cells 202 and 204 include a plurality of metallization layers (e.g., M0 layers carrying signals) that are interconnected with one another and/or to the terminals (e.g., gate, source, and a drain) of the MOSFETs. Since the second logic cell 204 is a mirror of the first logic cell 202, the vias proximate to the region in which the first logic cell 202 is adjacent to the second logic cell 204 (e.g., near power bus 208) are also mirrored. In this example, the gate vias 210 are proximate to one another on opposite sides of the power bus 208. Similarly, the diffusion vias 212 are proximate to one another on opposite sides of the power bus 208. The pitch 216 between the gate vias 210, as well as the pitch between the diffusion vias, are sufficiently large (e.g., being separated by the power bus 208) so as not to require the application of any special patterning or process operations during the fabrication of the mirrored arrangement of logic cells 200.

In the context of logic cell design, particularly when discussing the layout of logic cells in a mirrored manner within an IC, there are different methodologies that may be pursued in the placement and organization of the logic cells. According to aspects of the disclosure, the logic cells 200 shown in FIG. 2 are mirrored about the cell boundary line that bisects the power rail. This topology is referred to here as the “line-justified” methodology (see, e.g., cell height layout guide 110 in FIG. 1).

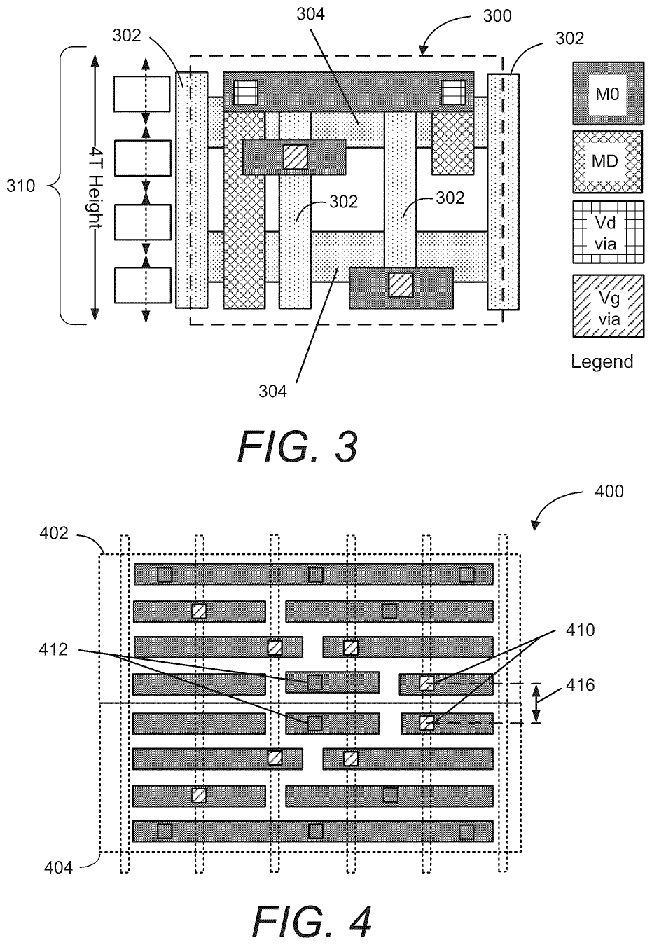

FIG. 3 illustrates a 4T logic cell 300 having a four-track (4T) height layout, according to aspects of the disclosure. In this example, the 4T logic cell 300 is configured as a NAND2 cell. Here, the 4T logic cell 300 includes a plurality of gate structures 302 and a plurality of doped regions 304 (e.g., forming the source/drain regions). Notably absent in FIG. 3 (when compared to logic cell 100 of FIG. 1) are the power buses. In the layout of the 4T logic cell 300, the power buses for Vdd and Vss are disposed on a backside of the logic cell to reduce the height of the 4T logic cell 300 to 4 tracks.

The 4T logic cell 300 further includes a plurality of metallization layers. In this example, two metallization layers are shown (although there may be many more depending on the configuration of the 4T logic cell 300), including metallization layer M0 and metallization layer MD (see Legend of FIG. 3). In an aspect, the metallization layer M0 is the first or the lowest metallization layer that is directly above the active components of the semiconductor device (e.g., the Metal-Oxide-Semiconductor Field-Effect Transistors (MOSFETs) within the 4T logic cell 300). As in the case of logic cell 100, the metallization layer M0 is often the metallization layer that is closest to the silicon substrate where the active devices are formed, while the metallization layer MD (e.g., Metal Drain metallization layer) forms the drain contacts of the MOSFETs of the 4T logic cell 300.

As in the case of the logic cell 100, the 4T logic cell 300 further includes a plurality of vias that interconnect the metallization layers of the 4T logic cell 300. In the example shown in FIG. 3, two via types are shown. Here, the illustrated vias include Vd vias and Vg vias (see Legend in FIG. 3). In an aspect, the Vd vias are responsible for connecting the diffusion regions of the MOSFETs to the appropriate metallization layer that connects the diffusion output (e.g., metallization layer MD) to other circuitry. In an aspect, the Vg vias connect the gate regions of the MOSFETs to the metallization layers above.

As in the case of the logic cell 100, logic cells 300 (e.g., 4T logic cell 300) may be stacked in a mirrored arrangement to construct more complex digital circuits that use the logic cells as their functional building blocks. FIG. 4 shows a mirrored arrangement of logic cells 400, according to aspects of the disclosure.

In FIG. 4, the mirrored arrangement of 4T logic cells 400 includes a first 4T logic cell 402 that is aligned with and adjacent a second logic cell 404. In this example, the first and second logic cells 402 and 404 may have the same layout as the 4T logic cell 300 shown in FIG. 3. Here, the first and second logic cells 402 and 404 are mirrored.

The first and second logic cells 402 and 404 include a plurality of metallization layers (e.g., M0 layers carrying signals) that are interconnected with one another and/or to the terminals (e.g., gate, source, and a drain) of the MOSFETs. Since the second logic cell 404 is a mirror of the first logic cell 402, the vias proximate to the region in which the first logic cell 402 and the second logic cell 404 are joined are also mirrored. In this example, the gate vias 410 are proximate to one another in a back-to-back arrangement, given that the power buses are disposed on the backside of logic cells 402 and 404. Similarly, the diffusion vias 412 are proximate to one another on opposite sides of the power bus 208 in a back-to-back arrangement. The pitch 416 between the gate vias 410, as well as the pitch (the same as pitch 416) between the diffusion vias, are substantially smaller than the pitch 216 shown between the gate vias 210 and diffusion vias 212 of logic cells 202 and 204 in FIG. 2.

According to aspects of the disclosure, the mirrored arrangement of logic cells 400 shown in FIG. 4 may be based on a space-justified methodology (see, e.g., cell height layout guide 310 in FIG. 3). Here, “space-justified” refers to a topology where the standard cells are mirrored about a cell boundary line that lies in the space between two metal lines.

Certain aspects of the disclosure are implemented with the recognition that the mirrored arrangement of 4T logic cells shown in FIG. 3 and FIG. 4 presents significantly different fabrication challenges than the mirrored arrangement of 5T logic cells shown in FIG. 1 and FIG. 2. While the pitch 216 between the vias at the edges of the 5T logic cells 202 and 204 are relatively large (e.g., on the order of two M0 metal pitches), the pitch 416 between the back-to-back gate vias 410 and back-to-back diffusion vias 412 is substantially smaller (e.g., on the order of a single M0 metal pitch). Given these substantially smaller distances, it becomes more difficult to reliably pattern and fabricate and isolate the small-scale back-to-back vias from one another. Further, the fabrication processes typically used to form the back-to-back vias on larger scale logic circuits (e.g., 5T logic circuits) may be unsuitable for fabricating the back-to-back vias at the substantially smaller distances on smaller scale logic circuits (e.g., 4T and lower height logic circuits). To fabricate such small-scale back-to-back vias, it may be necessary to employ expensive fabrication processes (e.g., double-patterned extreme ultraviolet (EUV) lithography). However, such expensive fabrication processes still may not achieve the desired consistency and reliability required for the close-spacing of the small-pitch back-to-back vias. For example, forming such small-scale back-to-back vias using a double pattern EUV process may still result in shorts between the small-scale back-to-back vias due to, for example, the collapse of the inter-dielectric layers between the back-to-back vias.

In accordance with certain aspects of the disclosure, a spacer is used to separate the small-pitch back-to-back vias of adjacent mirrored logic cells. In an aspect, the spacer may be fabricated from a nitride material (e.g., Si₃N₄), which is more resistant to etching than materials typically used for interlayer dielectrics (ILDs, e.g., SiO₂). By separating the small-scale back-to-back vias using such a spacer, the back-to-back vias are less likely to short with one another since the spacer is more robust at smaller dimensions than materials typically used for ILD. In an aspect, the use of such a spacer may also allow the adjacent back-to-back vias to be fabricated using more cost-efficient and conventional fabrication techniques. In an example, the spacer may be used to facilitate the fabrication of the back-to-back vias using trench-based patterning and etching techniques as opposed to direct metal etch processing.

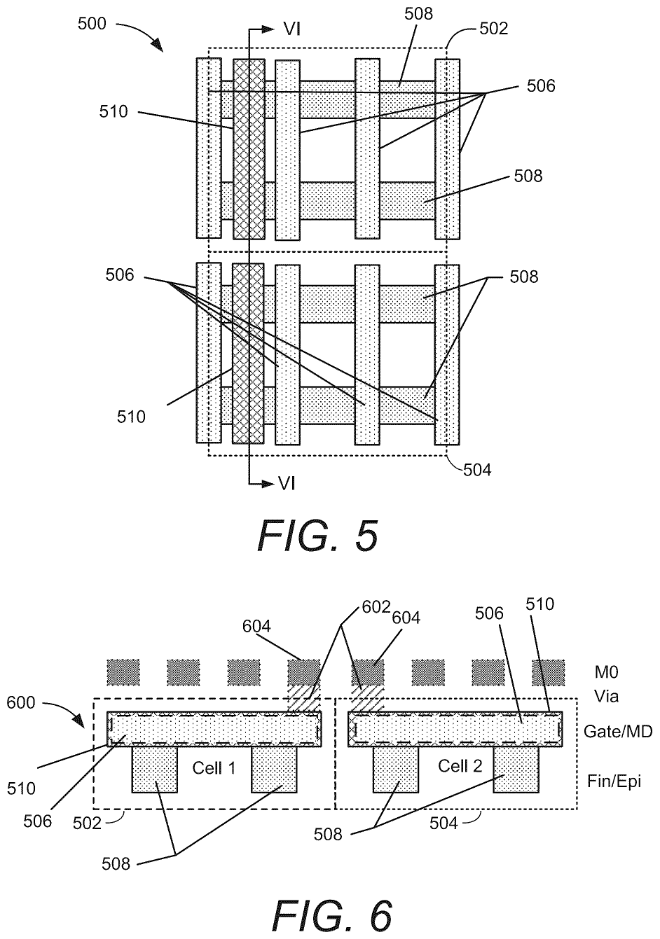

Certain advantages associated with the use of a spacer between small-scale back-to-back vias may be understood in the context of the fabrication processes used to form them. FIG. 5 is a top plan view showing an example of an intermediate structure 500 during the formation of a mirrored arrangement of 4T logic cells 502 and 504, according to aspects of the disclosure. In this example, the Front-End Of Line (FEOL) processes and Middle-Of-Line (MOL) processes have been completed (i.e., gate structures 506 and the rest of the FET structures 508 have already been formed in each of the 4T logic cells 502 and 504). Additionally, an MOL contact structure 510 (e.g., a structure of metallization layer MD) has been formed on each of the 4T logic cells 502 and 504.

FIG. 6 shows a cross-sectional view 600 of the intermediate structure 500 taken along line VI-VI of FIG. 5, according to aspects of the disclosure. Here, the cross-sectional view is in the plane of the MOL contacts 510. However, the gate conductor (while out of plane) is still represented as a dotted line. This indicates that the following fabrication operations are applicable to the formation of back-to-back vias connected to the gate structures (Vg vias) as well as back-to-back vias connected to the MOL contact (Vd via) structures 510. A goal of the following process operations includes forming closely spaced, back-to-back via structures 602 that connect with metallized structures 604 of, for example, the M0 metallization layer. However, based on the teachings of the present disclosure, it will be recognized that the process operations may be extended to V0 via structures formed above the M0 layer as well as to any higher via structures (e.g., V2, V3, etc.) that are connected to higher-level, small pitch metallization layers.

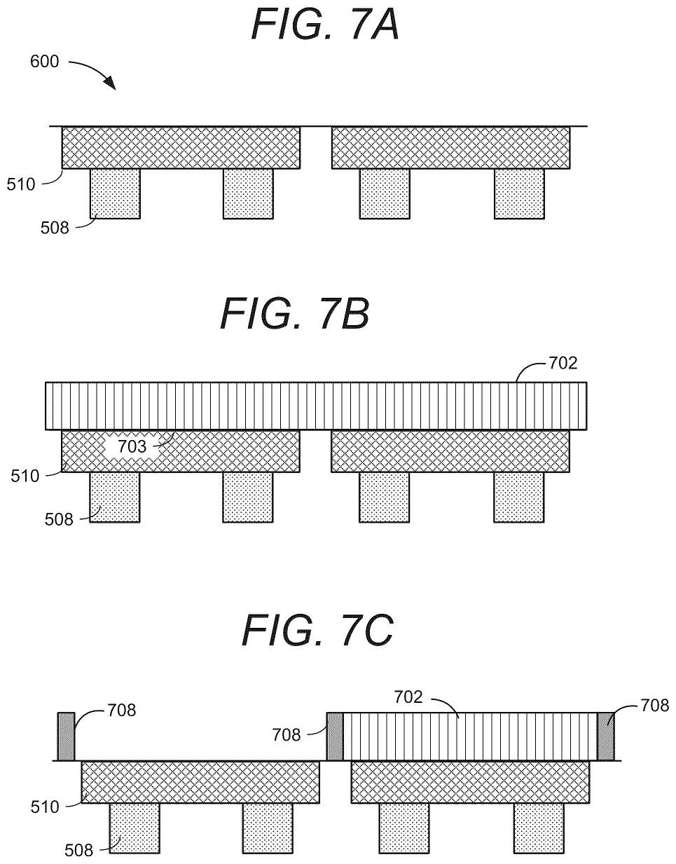

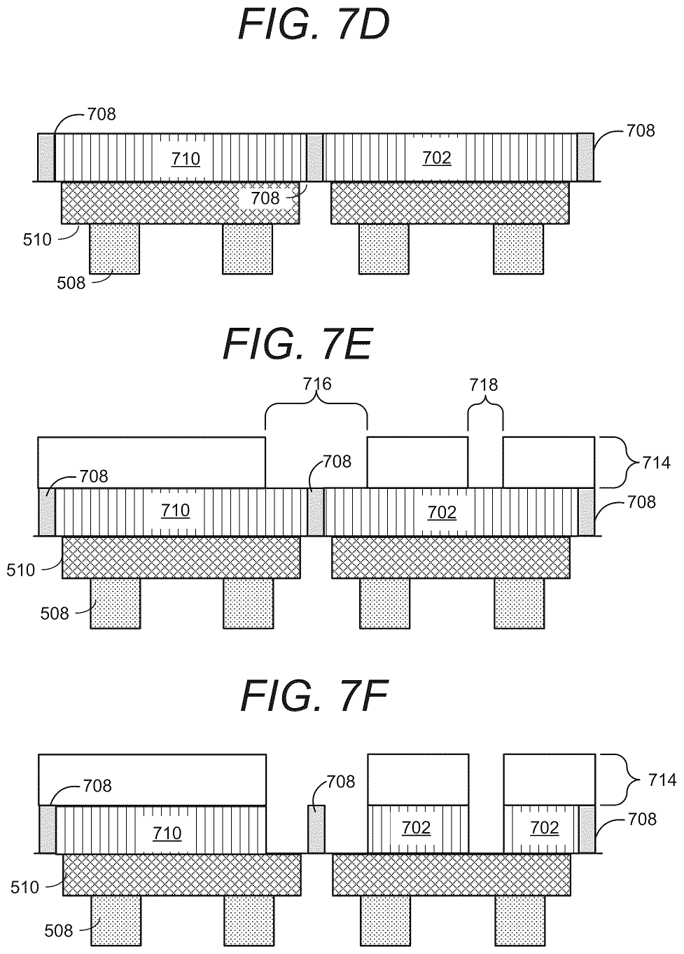

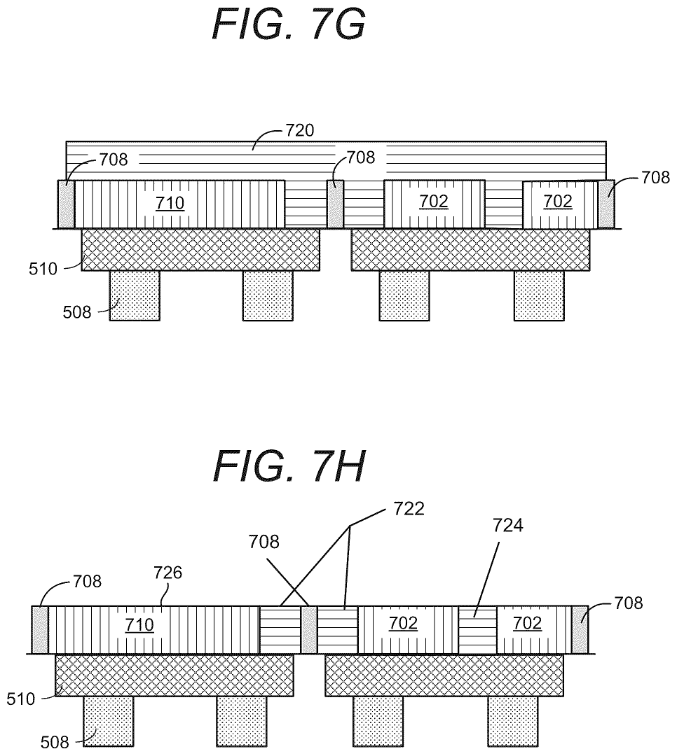

FIG. 7A through FIG. 7H show exemplary processing operations that may be used to form back-to-back vias in adjacent logic cells, according to aspects of the disclosure. In this example, each via is intended to provide a conductive path between structures of the M0 metallization layer and structures of the MOL contact. The two Vd vias are in close proximity, and referred to here as “back to back,” However, it will be recognized that the same exemplary processing operations may be used to form back-to-back Vg vias, with each Vg via providing a conductive path between structures of the M0 metallization layer and the gate structures 506.

FIG. 7A is a cross-sectional view 600 of the intermediate structure prior to initiating the processes that are specifically directed to fabricating the back-to-back Vd vias. In this example, the process for fabricating the back-to-back Vd vias begins in FIG. 7B, where a dielectric layer 702 is formed over a surface 703 of the intermediate structure. In FIG. 7C, the dielectric layer 702 has been patterned in rows. The remaining portions of the dielectric layer 702 are used as mandrels over which a spacer material (e.g., silicon nitride) is deposited and etched to form spacers 708.

In FIG. 7D, another dielectric layer 710 has been deposited over the upper surface and subject to a chemical mechanical polishing (CMP) process to level the upper surface of the dielectric layer 710 so that it is even with the upper surfaces of the dielectric layer 702 and spacers 708.

FIG. 7E through FIG. 7H show a sequence of processing operations that may be used to form the back-to-back Vd vias as well as other Vd vias. In FIG. 7E, a resist layer 714 is deposited over the upper surfaces of the dielectric layers 702 and 710 and spacers 708. In an aspect, the Vd vias, including the back-to-back Vd vias, are fabricated using a damascene process. In an aspect, the resulting vias may have isotropic crystalline metal structures when formed using electroplating employed in such damascene processing.

As shown in FIG. 7E, the resist layer 714 is patterned with open areas overlying the regions of the dielectric layers 702 and 710 that are to be removed for depositing the metal that will form the Vd vias. Here, an open region 716 that will be used to form the back-to-back Vd vias overlies the dielectric layers 702, 710 and the spacer 708 separating the dielectric layers 702, 710. A further open region 718 overlies a portion of the dielectric layer 702 that will be used to form another Vd via.

In FIG. 7F, the portions of the dielectric layers 702 and 710 below the open regions 716 and 718 have been removed. In an aspect, the material used to form the spacers 708 is resistant to removal by the etchant used to remove the exposed regions of the dielectric layers 702 and 710.

In FIG. 7G, the resist layer 714 has been removed and a layer of metallization 720 has been deposited over the surface of the dielectric layers 702 and 710 and fills the portions of the dielectric layers that were removed during the etching process. The layer of metallization 720 also covers the spacer 708 separating dielectric layer 702 from dielectric layer 710. In an aspect, the layer metallization 720 may be deposited using an electroplating process, electroless plating process, chemical vapor deposition process, or any other metal deposition process conventionally used to deposit metallization structures.

In FIG. 7H, the layer of metallization 720 has been subject to a CMP process to level the layer of metallization 720. The leveling of the layer of metallization 720 leaves behind a pair of back-to-back Vd vias 722 separated by a spacer 708 as well as a further Vd via 724 in the dielectric layer 702. In an aspect, the Vd vias 722 directly abut opposite sides of the spacer 708. Subsequent metal layer build operations may be used to form further metallization layers (e.g., a patterned M0 metallization layer) over the surface 726, where the Vd vias provide a conductive path between the metallization structures of the MOL contact layer and the metallization layer above.

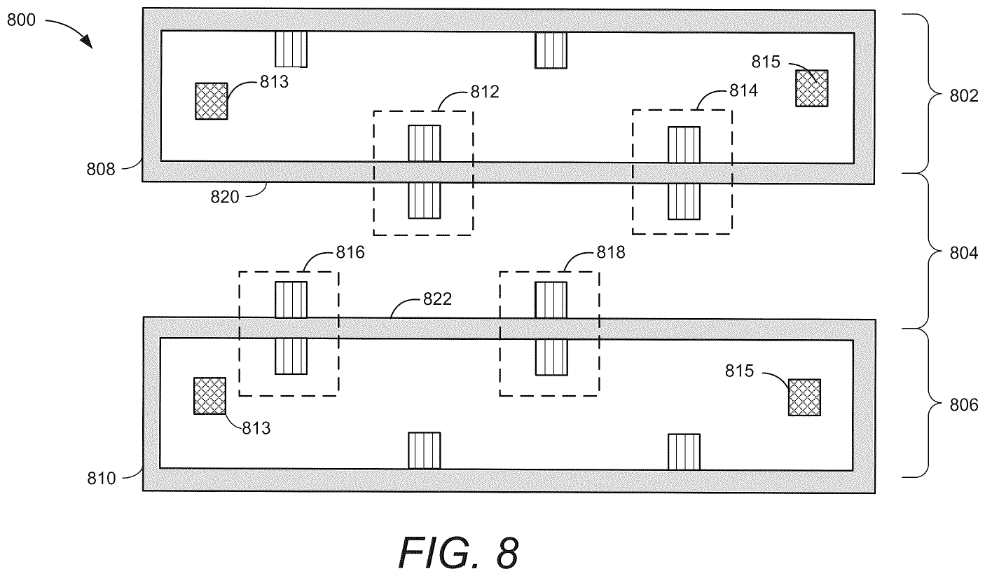

FIG. 8 is a plan view of an example arrangement of logic rows 800, according to aspects of the disclosure. In an aspect, each logic row may be formed from multiple logic cells. In this example, the multi-row arrangement of logic cells 800 includes a first logic row 802, a second logic row 804 adjacent to the first logic row 802, and a third logic row 806 adjacent to the second logic row 804. A first spacer structure 808 is formed about the peripheral edge of the first logic row 802 and, in an aspect, may form a peripheral boundary surrounding the first logic row 802. In an aspect, the spacer structure 808 separates a first pair of back-to-back vias 812 from one another as well as a second pair of back-to-back vias 814 from one another. In an aspect, the first pair of back-to-back vias 812 may be Vg vias, and the second pair of back-to-back vias 814 may be Vd vias. A second spacer structure 810 is formed about a peripheral edge of the third logic row 806 and, in an aspect, may form a peripheral boundary surrounding the third logic row 806. The second spacer structure 810 separates a third pair of back-to-back vias 816 from one another as well as a fourth pair of back-to-back vias 816 from one another. In an aspect, the third pair of back-to-back vias 816 may be Vd vias, and the fourth pair of back-to-back vias 814 may be Vg vias. In an aspect, the logic rows 802, 804 and 806 may also include standard Vg vias (e.g., vias 813) and standard Vd vias (e.g., vias 815).

Edge 820 of the first spacer structure 808 may require a higher level of fabrication accuracy than the other edges of the spacer structure 808 since edge 820 separates the first pair of back-to-back vias 812 from one another as well as the second pair of back-to-back vias 814 from one another. Similarly, edge 822 of the second spacer structure 810 may require a higher level of fabrication accuracy than the other edges of the second spacer structure 810 since edge 822 separates the third pair of back-to-back vias 816 from one another as well as the fourth pair of back-to-back vias 818 from one another. In an aspect, the mandrel patterns of the dielectric layers used to form the spacer structures 808 and 810 may be optimized using unidirectional Source/Mask Optimization (SMO) and Optical Proximity Correction (OPC) tuning.

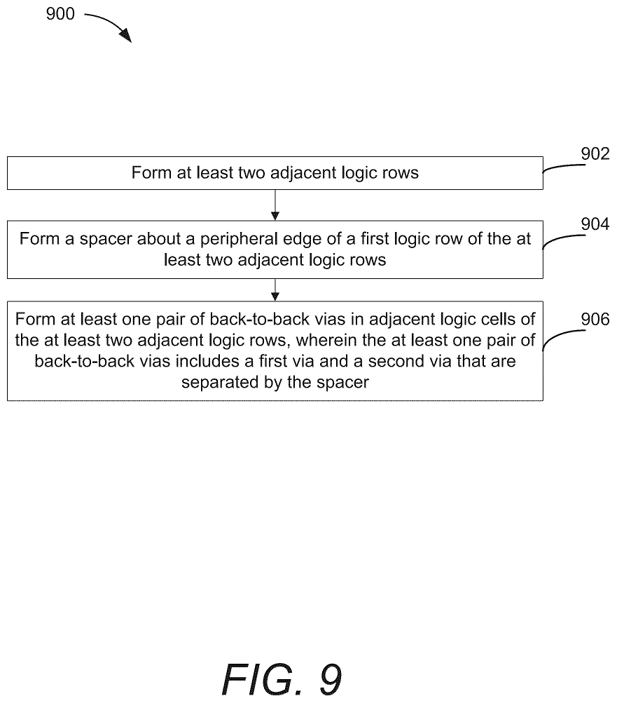

FIG. 9 is a flowchart showing an example method 900 for fabricating a semiconductor logic device, according to aspects of the disclosure. At operation 902, at least two adjacent logic rows are formed. At operation 904, a spacer is formed about a peripheral edge of a first logic row of the at least two adjacent logic rows. At operation 906, at least one pair of back-to-back vias is formed in adjacent logic cells of the at least two adjacent logic rows, wherein the at least one pair of back-to-back vias includes a first via and a second via that are separated by the spacer.

In some aspects, the first via of the at least one pair of back-to-back vias is formed to abut a first side of the spacer; and the second via of the at least one pair of back-to-back is formed to abut a second side of the spacer opposite the first side of the spacer.

In some aspects, the spacer is formed from silicon nitride.

In some aspects, the spacer forms a peripheral boundary surrounding the first logic row.

In some aspects, the first via and the second via are formed using a Damascene process.

In some aspects, the method includes forming a third logic row adjacent to a second logic row of the at least two adjacent logic rows; forming a further spacer about a peripheral boundary of the third logic row; and forming at least one further pair of back-to-back vias, wherein a first via of the further pair of back-to-back vias is associated with a logic cell of the second logic row and a second via of the further pair of back-to-back vias is associated with a logic cell of the third logic row, and wherein the first via of the further pair of back-two-back vias is separated from the second via of the further pair of back-two-back vias by the further spacer.

In some aspects, the further spacer is formed from silicon nitride.

In some aspects, the adjacent logic cells of the at least two adjacent logic rows are each formed based on 4 track (4T), space-justified layouts.

A technical advantage of the method 900 is that it may be used to form back-to-back via structures on adjacent logic cells based on very small pitches between the via structures. In an aspect, the back-to-back via structures may be formed using low-cost patterning (e.g. immersion lithography) and conventional metallization processes (e.g., Damascene via-fill processes). In this description, the illustrations have focused on Vias Vd and Vg (below M0). However, based on the teachings of the present disclosure, it will be recognized that method 900 may be used to fabricate other tightly spaced vias farther up the metallization stack (e.g. V0, V1, V2, etc.).

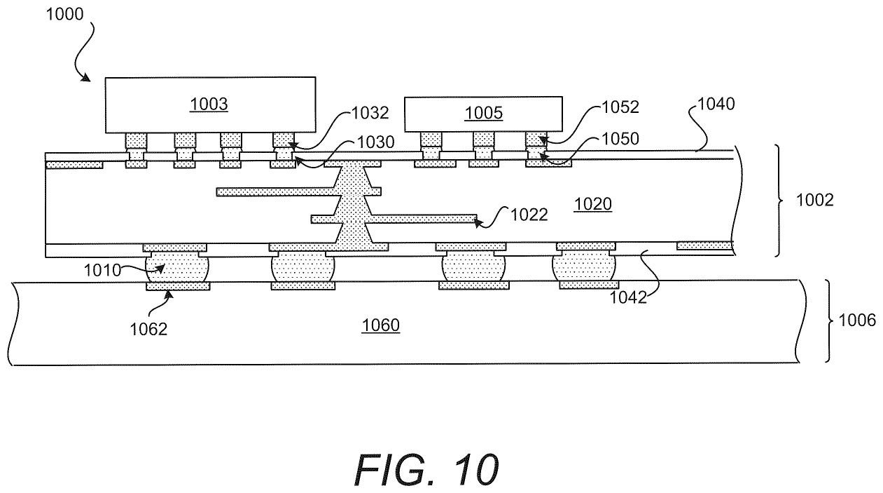

FIG. 10 illustrates a profile view of a package 1000 that includes a surface mount substrate 1002, an integrated device 1003, and an integrated passive device 1005, according to aspects of the disclosure. The package 1000 may be coupled to a printed circuit board (PCB) 1006 through a plurality of solder interconnects 1010. The PCB 1006 may include at least one board dielectric layer 1060 and a plurality of board interconnects 1062.

The surface mount substrate 1002 includes at least one dielectric layer 1020 (e.g., substrate dielectric layer), a plurality of interconnects 1022 (e.g., substrate interconnects), a solder resist layer 1040 and a solder resist layer 1042. The integrated device 1003 may be coupled to the surface mount substrate 1002 through a plurality of solder interconnects 1030. The integrated device 1003 may be coupled to the surface mount substrate 1002 through a plurality of pillar interconnects 1032 and the plurality of solder interconnects 1030. The integrated passive device 1005 may be coupled to the surface mount substrate 1002 through a plurality of solder interconnects 1050. The integrated passive device 1005 may be coupled to the surface mount substrate 1002 through a plurality of pillar interconnects 1052 and the plurality of solder interconnects 1050.

The package (e.g., 1000) may be implemented in a radio frequency (RF) package. The RF package may be a radio frequency front end (RFFE) package. A package (e.g., 1000) may be configured to provide Wireless Fidelity (WiFi) communication and/or cellular communication (e.g., 2G, 3G, 4G, 5G). The package (e.g., 1000) may be configured to support Global System for Mobile (GSM) Communications, Universal Mobile Telecommunications System (UMTS), and/or Long-Term Evolution (LTE). The package (e.g., 1000) may be configured to transmit and receive signals having different frequencies and/or communication protocols.

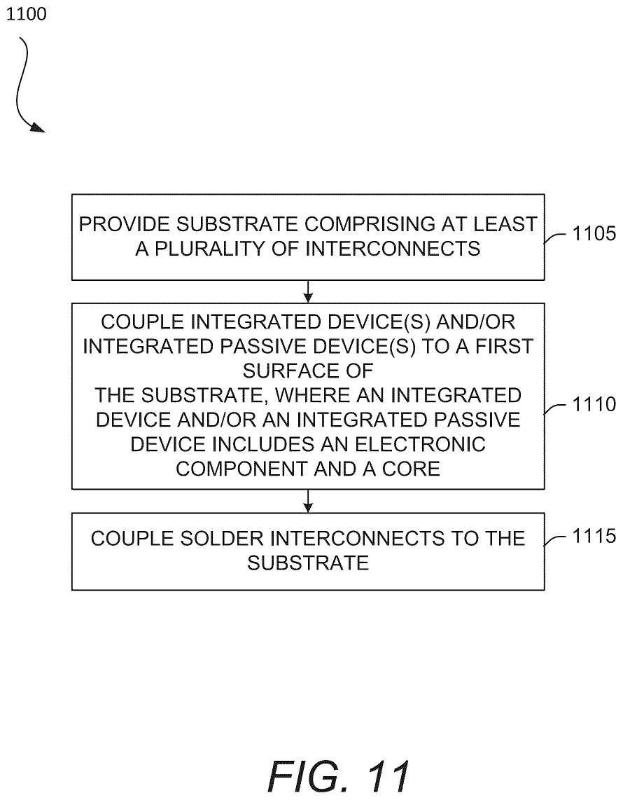

FIG. 11 illustrates an example method 1100 for providing or fabricating a package that includes an integrated device comprising adjacent logic cells having back-to-back vias, according to aspects of the disclosure. In some implementations, the method 1100 of FIG. 11 may be used to provide or fabricate the package 1000 of FIG. 10 described in the disclosure. However, the method 1100 may be used to provide or fabricate any of the packages described in the disclosure.

It should be noted that the method of FIG. 11 may combine one or more processes in order to simplify and/or clarify the method for providing or fabricating a package that includes an integrated device comprising adjacent logic circuits having back-to-back vias, according to aspects of the disclosure. In some implementations, the order of the processes may be changed or modified.

The method provides (at 1105) a substrate (e.g., 1002). The substrate 1002 may be provided by a supplier or fabricated. The substrate 1002 includes at least one dielectric layer 1020, and a plurality of interconnects 1022. The substrate 1002 may include an embedded trace substrate (ETS). In some implementations, the at least one dielectric layer 1020 may include prepreg layers.

The method couples (at 1110) at least one integrated device (e.g., 1003) to the first surface of the substrate (e.g., 1002). For example, the integrated device 1003 may be coupled to the substrate 1002 through the plurality of pillar interconnects 1032 and the plurality of solder interconnects 1030. The plurality of pillar interconnects 1032 may be optional. The plurality of solder interconnects 1030 are coupled to the plurality of interconnects 1022. A solder reflow process may be used to couple the integrated device 1003 to the plurality of interconnects through the plurality of solder interconnects 1030.

The method also couples (at 1110) at least one integrated passive device (e.g., 1005) to the first surface of the substrate (e.g., 1002). For example, the integrated passive device 1005 may be coupled to the substrate 1002 through the plurality of pillar interconnects 1052 and the plurality of solder interconnects 1050. The plurality of pillar interconnects 1052 may be optional. The plurality of solder interconnects 1050 are coupled to the plurality of interconnects 1022. A solder reflow process may be used to couple the integrated passive device 1005 to the plurality of interconnects through the plurality of solder interconnects 1050.

The method couples (at 1115) a plurality of solder interconnects (e.g., 1010) to the second surface of the substrate (e.g., 1002). A solder reflow process may be used to couple the plurality of solder interconnects 1010 to the substrate.

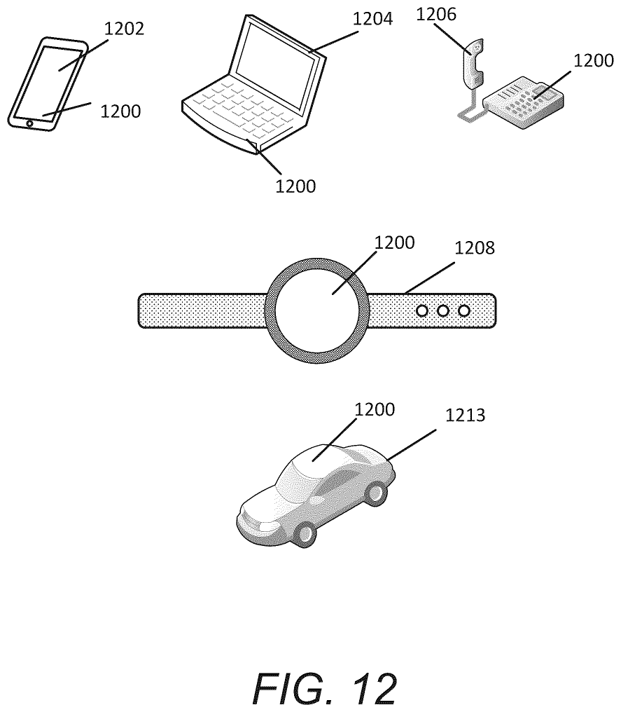

FIG. 12 illustrates various electronic devices that may be integrated with any of the aforementioned devices, integrated devices, integrated circuit (IC) packages, integrated circuit (IC) devices, semiconductor devices, integrated circuits, electronic components, interposer packages, package-on-package (POP), System in Package (SiP), or System on Chip (SoC). For example, a mobile phone device 1202, a laptop computer device 1204, a fixed location terminal device 1206, a wearable device 1208, or automotive vehicle 1213 may include a device 1200 as described herein. The device 1200 may be, for example, any of the devices and/or integrated circuit (IC) packages described herein. The devices 1202, 1204, 1206 and 1208 and the vehicle 1213 illustrated in FIG. 12 are merely exemplary. Other electronic devices may also feature the device 1200 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

Implementation examples are described in the following numbered aspects:
Aspect 1. An electronic device having at least two adjacent logic cells, the at least two adjacent logic cells comprising: at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and a spacer disposed between and separating the first via and the second via.
Aspect 2. The electronic device of aspect 1, wherein: the first via abuts a first side of the spacer; and the second via abuts a second side of the spacer opposite the first side of the spacer.
Aspect 3. The electronic device of any of aspects 1 to 2, wherein: the spacer comprises silicon nitride.
Aspect 4. The electronic device of any of aspects 1 to 3, wherein: the spacer forms a peripheral boundary about the first logic cell.
Aspect 5. The electronic device of any of aspects 1 to 4, wherein: the first via and the second via have isotropic crystalline metal structures.
Aspect 6. The electronic device of any of aspects 1 to 5, wherein: the second logic cell includes a peripheral edge opposite the first logic cell; the electronic device further comprising: a third logic cell adjacent the peripheral edge of the second logic cell; at least one further pair of back-to-back vias, wherein a third via of the further pair of back-to-back vias is associated with the second logic cell and a fourth via of the further pair of back-to-back vias is associated with the third logic cell; and a further spacer disposed between and separating the third via and the fourth via.
Aspect 7. The electronic device of aspect 6, wherein: the further spacer comprises silicon nitride.
Aspect 8. The electronic device of aspect 7, wherein: the further spacer forms a peripheral boundary about the third logic cell.
Aspect 9. The electronic device of any of aspects 1 to 8, wherein: the at least two adjacent logic cells each have 4 track (4T) layouts.
Aspect 10. The electronic device of aspect 9, wherein: the 4T layouts are space-justified.
Aspect 11. The electronic device of any of aspects 1 to 10, wherein the electronic device comprises at least one of: a music player; a video player; an entertainment unit; a navigation device; a communications device; a mobile device; a mobile phone; a smartphone; a personal digital assistant; a fixed location terminal; a tablet computer, a computer; a wearable device; a laptop computer; a server; an internet of things (IoT) device; or a device in an automotive vehicle.
Aspect 12. A semiconductor logic device having at least two adjacent logic cells, the at least two adjacent logic cells comprising: at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and a spacer disposed between and separating the first via and the second via.
Aspect 13. The semiconductor logic device of aspect 12, wherein: the first via abuts a first side of the spacer; and the second via abuts a second side of the spacer opposite the first side of the spacer.
Aspect 14. The semiconductor logic device of any of aspects 12 to 13, wherein: the spacer comprises silicon nitride.
Aspect 15. The semiconductor logic device of any of aspects 12 to 14, wherein: the spacer forms a peripheral boundary about the first logic cell.
Aspect 16. The semiconductor logic device of any of aspects 12 to 15, wherein: the first via and the second via have isotropic crystalline metal structures.
Aspect 17. The semiconductor logic device of any of aspects 12 to 16, wherein: the second logic cell includes a peripheral edge opposite the first logic cell; the semiconductor logic device further comprising: a third logic cell adjacent the peripheral edge of the second logic cell; at least one further pair of back-to-back vias, wherein a third via of the further pair of back-to-back vias is associated with the second logic cell and a fourth via of the further pair of back-to-back vias is associated with the third logic cell; and a further spacer disposed between and separating the third via and the fourth via.
Aspect 18. The semiconductor logic device of aspect 17, wherein: the further spacer comprises silicon nitride.
Aspect 19. The semiconductor logic device of aspect 18, wherein: the further spacer forms a peripheral boundary about the third logic cell.
Aspect 20. The semiconductor logic device of any of aspects 12 to 19, wherein: the at least two adjacent logic cells each have 4 track (4T) layouts.
Aspect 21. The semiconductor logic device of aspect 20, wherein: the 4T layouts are space-justified.
Aspect 22. A method of forming a semiconductor logic device, comprising: forming at least two adjacent logic rows; forming a spacer about a peripheral edge of a first logic row of the at least two adjacent logic rows; and forming at least one pair of back-to-back vias in adjacent logic cells of the at least two adjacent logic rows, wherein the at least one pair of back-to-back vias includes a first via and a second via that are separated by the spacer.
Aspect 23. The method of aspect 22, wherein: the first via of the at least one pair of back-to-back vias is formed to abut a first side of the spacer; and the second via of the at least one pair of back-to-back is formed to abut a second side of the spacer opposite the first side of the spacer.
Aspect 24. The method of any of aspects 22 to 23, wherein: the spacer is formed from silicon nitride.
Aspect 25. The method of any of aspects 22 to 24, wherein: the spacer forms a peripheral boundary surrounding the first logic row.
Aspect 26. The method of any of aspects 22 to 25, wherein: the first via and the second via are formed using a Damascene process.
Aspect 27. The method of any of aspects 25 to 26, further comprising: forming a third logic row adjacent to a second logic row of the at least two adjacent logic rows; forming a further spacer about a peripheral boundary of the third logic row; and forming at least one further pair of back-to-back vias, wherein a first via of the further pair of back-to-back vias is associated with a logic cell of the second logic row and a second via of the further pair of back-to-back vias is associated with a logic cell of the third logic row, and wherein the first via of the further pair of back-two-back vias is separated from the second via of the further pair of back-two-back vias by the further spacer.
Aspect 28. The method of aspect 27, wherein: the further spacer is formed from silicon nitride.
Aspect 29. The method of any of aspects 22 to 28, wherein: the adjacent logic cells of the at least two adjacent logic rows are each formed based on 4 track (4T), space-justified layouts.

It is noted that the figures in the disclosure may represent actual representations and/or conceptual representations of various parts, components, objects, devices, packages, integrated devices, integrated circuits, and/or transistors. In some instances, the figures may not be to scale. In some instances, for the purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another-even if they do not directly physically touch each other. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The term “encapsulating” means that the object may partially encapsulate or completely encapsulate another object. The terms “top” and “bottom” are arbitrary. A component that is located on top may be located over a component that is located on the bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. The term “about ‘value X”, or “approximately value X”, as used in the disclosure means within 10 percent of the ‘value X’. For example, a value of about 1 or approximately 1, would mean a value in a range of 0.9-1.1.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under-bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metallization layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the detailed description above, it can be seen that different features are grouped together in examples. This manner of disclosure should not be understood as an intention that the example aspects have more features than are explicitly mentioned in each aspect. Rather, the various aspects of the disclosure may include fewer than all features of an individual example aspect disclosed. Therefore, the following aspects should hereby be deemed to be incorporated in the description, wherein each aspect by itself can stand as a separate example. Although each dependent aspect can refer in the aspects to a specific combination with one of the other aspects, the aspect(s) of that dependent aspect are not limited to the specific combination. It will be appreciated that other example aspects can also include a combination of the dependent aspect(s) with the subject matter of any other dependent aspect or independent aspect or a combination of any feature with other dependent and independent aspects. The various aspects disclosed herein expressly include these combinations, unless it is explicitly expressed or can be readily inferred that a specific combination is not intended (e.g., contradictory aspects, such as defining an element as both an electrical insulator and an electrical conductor). Furthermore, it is also intended that aspects of an aspect can be included in any other independent aspect, even if the aspect is not directly dependent on the independent aspect.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An electronic device having at least two adjacent logic cells, the at least two adjacent logic cells comprising:
at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and
a spacer disposed between and separating the first via and the second via.

2. The electronic device of claim 1, wherein:
the first via abuts a first side of the spacer; and
the second via abuts a second side of the spacer opposite the first side of the spacer.

3. The electronic device of claim 1, wherein:
the spacer comprises silicon nitride.

4. The electronic device of claim 1, wherein:
the spacer forms a peripheral boundary about the first logic cell.

5. The electronic device of claim 1, wherein:
the first via and the second via have isotropic crystalline metal structures.

6. The electronic device of claim 1, wherein:
the second logic cell includes a peripheral edge opposite the first logic cell;
the electronic device further comprising:
a third logic cell adjacent the peripheral edge of the second logic cell;
at least one further pair of back-to-back vias, wherein a third via of the further pair of back-to-back vias is associated with the second logic cell and a fourth via of the further pair of back-to-back vias is associated with the third logic cell; and
a further spacer disposed between and separating the third via and the fourth via.

7. The electronic device of claim 6, wherein:
the further spacer comprises silicon nitride.

8. The electronic device of claim 7, wherein:
the further spacer forms a peripheral boundary about the third logic cell.

9. The electronic device of claim 1, wherein the electronic device comprises at least one of:
a music player;
a video player;
an entertainment unit;
a navigation device;
a communications device;
a mobile device;
a mobile phone;
a smartphone;
a personal digital assistant;
a fixed location terminal;
a tablet computer, a computer;
a wearable device;
a laptop computer;
a server;
an internet of things (IoT) device; or
a device in an automotive vehicle.

10. A semiconductor logic device having at least two adjacent logic cells, the at least two adjacent logic cells comprising:
at least one pair of back-to-back vias, wherein a first via of the pair of back-to-back vias is associated with a first logic cell of the at least two adjacent logic cells and a second via of the pair of back-to-back vias is associated with a second logic cell of the at least two adjacent logic cells; and
a spacer disposed between and separating the first via and the second via.

11. The semiconductor logic device of claim 10, wherein:
the first via abuts a first side of the spacer; and
the second via abuts a second side of the spacer opposite the first side of the spacer.

12. The semiconductor logic device of claim 10, wherein:
the spacer comprises silicon nitride.

13. The semiconductor logic device of claim 10, wherein:
the spacer forms a peripheral boundary about the first logic cell.

14. The semiconductor logic device of claim 10, wherein:
the second logic cell includes a peripheral edge opposite the first logic cell;
the semiconductor logic device further comprising:
a third logic cell adjacent the peripheral edge of the second logic cell;
at least one further pair of back-to-back vias, wherein a third via of the further pair of back-to-back vias is associated with the second logic cell and a fourth via of the further pair of back-to-back vias is associated with the third logic cell; and
a further spacer disposed between and separating the third via and the fourth via.

15. The semiconductor logic device of claim 14, wherein:
the further spacer comprises silicon nitride.

16. The semiconductor logic device of claim 15, wherein:
the further spacer forms a peripheral boundary about the third logic cell.

17. A method of forming a semiconductor logic device, comprising:
forming at least two adjacent logic rows;
forming a spacer about a peripheral edge of a first logic row of the at least two adjacent logic rows; and
forming at least one pair of back-to-back vias in adjacent logic cells of the at least two adjacent logic rows, wherein the at least one pair of back-to-back vias includes a first via and a second via that are separated by the spacer.

18. The method of claim 17, wherein:
the first via of the at least one pair of back-to-back vias is formed to abut a first side of the spacer; and
the second via of the at least one pair of back-to-back is formed to abut a second side of the spacer opposite the first side of the spacer.

19. The method of claim 17, wherein:
the spacer forms a peripheral boundary surrounding the first logic row.

20. The method of claim 19, further comprising:
forming a third logic row adjacent to a second logic row of the at least two adjacent logic rows;
forming a further spacer about a peripheral boundary of the third logic row; and
forming at least one further pair of back-to-back vias, wherein a first via of the further pair of back-to-back vias is associated with a logic cell of the second logic row and a second via of the further pair of back-to-back vias is associated with a logic cell of the third logic row, and wherein the first via of the further pair of back-two-back vias is separated from the second via of the further pair of back-two-back vias by the further spacer.
